(19) United States
(12) Patent Application Publication
(10) Pub. No.: US 2025/0329254 A1
(43) Pub. Date: Oct. 23, 2025

(54) INFORMATION PROCESSING SYSTEM, INFORMATION PROCESSING METHOD, AND NON-TRANSITORY COMPUTER READABLE STORAGE MEDIUM STORING INFORMATION PROCESSING PROGRAM

(71) Applicant: TOYOTA JIDOSHA KABUSHIKI KAISHA, Toyota-shi (JP)

(72) Inventors: Masataka OKUDA, Toyota-shi (JP); Kanade KURIYAMA, Toyota-shi (JP); Masatoshi KAKUTANI, Miyoshi-shi (JP); Kaoru YOSHIDA, Nisshin-shi (JP); Toshiki SHINOHARA, Toyota-shi (JP)

(73) Assignee: TOYOTA JIDOSHA KABUSHIKI KAISHA, Toyota-shi (JP)

(21) Appl. No.: 19/078,364

(22) Filed: Mar. 13, 2025

(30) Foreign Application Priority Data
Apr. 22, 2024 (JP) 2024-069105

(51) Int. Cl. G08G 1/01

(52) U.S. Cl. CPC G08G 1/0129; G08G 1/0145

(57) ABSTRACT

An information processing system includes a communication device that sequentially acquires moving body information, which includes information that indicates a position of a moving body located in a real world. The information processing system includes a processing device that calculates predicted moving body information, which indicates a predicted position of the moving body at a time after the moving body information was acquired, at a predetermined cycle. The processing device evaluates a correspondence relationship between a position of the moving body indicated by the predicted moving body information at a third time and calculated from moving body information that was acquired at a first time and a position of the moving body at the third time acquired from moving body information that was acquired at a second time, which is different from the first time, and determines the predetermined update cycle based on the evaluation.

### CROSS-REFERENCE TO RELATED APPLICATIONS

This application is based upon and claims the benefit of priority from Japanese Patent Application No. 2024-069105, filed on Apr. 22, 2024 the entire contents of which are incorporated herein by reference.

### BACKGROUND

### 1. Field

The present disclosure relates to an information processing system, an information processing method, and a non-transitory computer readable storage medium storing an information processing program for reproducing a real-world traffic environment in a virtual space.

### 2. Description of Related Art

A digital twin is a technology that reproduces an environment identical to the real world in a virtual space. Japanese Laid-Open Patent Publication No. 2020-013557 discloses a system that utilizes a traffic digital twin to reproduce a real-world traffic environment in a virtual space.

To accurately reproduce the real-world positions of moving bodies in a virtual space, one approach is to minimize the update cycle for the positions of the moving bodies in the real world. However, this significantly increases the processing load on the device responsible for updating the positions of the moving bodies.

### SUMMARY

This Summary is provided to introduce a selection of concepts in a simplified form that are further described below in the Detailed Description. This Summary is not intended to identify key characteristics or essential characteristics of the claimed subject matter, nor is it intended to be used as an aid in determining the scope of the claimed subject matter.

An information processing system according to an aspect of the present disclosure includes a communication device configured to sequentially acquire moving body information. The moving body information includes information that indicates a position of a moving body located in a real world. The information processing system includes a processing device configured to calculate predicted moving body information based on the moving body information at a predetermined update cycle. The predicted moving body information indicates a predicted position of the moving body at a time after the moving body information was acquired. The processing device is configured to evaluate a correspondence relationship between a position of the moving body indicated by the predicted moving body information at a third time and calculated from moving body information that was acquired at a first time and a position of the moving body at the third time acquired from moving body information that was acquired at a second time. The second time is different from the first time. The processing device is configured to determine the predetermined update cycle based on the evaluation.

An information processing method according to an aspect of the present disclosure includes sequentially acquiring moving body information. The moving body information includes information that indicates a position of a moving body located in a real world. The information processing method includes calculating predicted moving body information based on the moving body information at a predetermined update cycle. The predicted moving body information indicates a predicted position of the moving body at a time after the moving body information was acquired. The information processing method includes evaluating a correspondence relationship between a position of the moving body indicated by the predicted moving body information at a third time and calculated from moving body information that was acquired at a first time and a position of the moving body at the third time acquired from moving body information that was acquired at a second time. The second time is different from the first time. The information processing method includes determining the predetermined update cycle based on the evaluation.

A non-transitory computer readable storage medium storing an information processing program according to an aspect of the present disclosure is executed by a processing device of an information processing system. The information processing system includes a communication device configured to sequentially acquire moving body information. The moving body information includes information indicating a position of a moving body located in a real world. The information processing program causes the processing device to execute calculating predicted moving body information based on the moving body information at a predetermined update cycle. The predicted moving body information indicates a predicted position of the moving body at a time after the moving body information was acquired. The information processing program causes the processing device to execute evaluating a correspondence relationship between a position of the moving body indicated by the predicted moving body information at a third time and calculated from moving body information that was acquired at a first time and a position of the moving body at the third time acquired from moving body information that was acquired at a second time. The second time is different from the first time. The information processing program causes the processing device to execute determining the predetermined update cycle based on the evaluation.

Other features and aspects will be apparent from the following detailed description, the drawings, and the claims.

### BRIEF DESCRIPTION OF THE DRAWINGS

FIG. 1 is a schematic diagram illustrating an information processing system according to an embodiment.

FIG. 2 is a schematic diagram illustrating a processing device, a communication device, and a storage device included in the information processing system shown in FIG. 1.

FIG. 3 is a flowchart illustrating a series of processes executed by the information processing system shown in FIG. 1.

FIG. 4 is a schematic diagram illustrating the moving bodies within each zone.

FIG. 5 is a schematic diagram showing the magnitude of the deviation between the predicted position of the moving body in the predicted moving body information and the predicted position of the moving body in the test predicted moving body information.

FIG. 6 is a table illustrating the method for calculating similarity, which is an index value indicating the degree of similarity.

FIG. 7 is a table illustrating the relationship between the similarity rate, which is an index value indicating the degree of similarity for each of the zones in FIG. 4, and the update cycle of the predicted moving body information for each zone in FIG. 4.

FIG. 8 is a flowchart illustrating a series of processes executed by the information processing system according to the second embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### First Embodiment

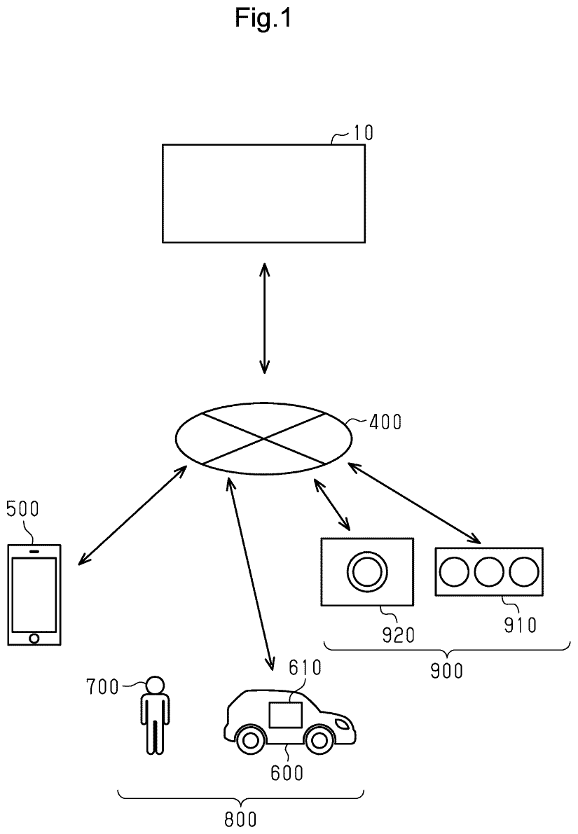

An information processing system according to a first embodiment will now be described with reference to FIGS. 1 to 7.

### Overview of Information Processing System 10

An information processing system 10 acquires moving body information, which indicates the position of each of multiple moving bodies 800 in the real world, at multiple times. The moving bodies 800 include vehicles 600, pedestrians 700, bicycles, and animals. The vehicles 600 include two-wheeled vehicles.

The information processing system 10 calculates, using the acquired moving body information, predicted moving body information at a predetermined update cycle. The predicted moving body information indicates the predicted position of each moving body 800 at a time after the moving body information was acquired. The predicted moving body information reproduces the real-world traffic environment in a virtual space.

As shown in FIG. 1, the information processing system 10 is configured to communicate with multiple information processing terminals 500 (only one is shown), multiple vehicles 600 (only one is shown), and multiple roadside sensors 900 via an external communication network 400.

Referring to FIG. 1, the information processing terminal 500 is capable of collecting the position information of a pedestrian 700 carrying the information processing terminal 500 as moving body information. The position information is represented by coordinate values of latitude and longitude. The information processing terminal 500 transmits the collected position information of the pedestrian 700 to the information processing system 10 via the external communication network 400. The information processing terminal 500 is, for example, a smartphone carried by the pedestrian 700. The information processing terminal 500 may also be, for example, a wearable terminal or a tablet terminal. Examples of the wearable terminal include a ring-type terminal worn on the wrist and a necklace-type terminal worn on the neck.

The vehicle 600 shown in FIG. 1 includes a vehicle on-board sensor 610. The vehicle 600 transmits the moving body information collected by the vehicle on-board sensor 610 to the information processing system 10 via the external communication network 400. Examples of the vehicle on-board sensor 610 include a vehicle speed sensor, an accelerator sensor, a brake sensor, a steering sensor, and an acceleration sensor. The acceleration sensor is, for example, an inertial measurement unit (IMU).

The vehicle 600 includes an external camera, a sonar, and a position information acquisition system as the vehicle on-board sensor 610. The external camera and the sonar mounted on the vehicle 600 collect information on distances between the vehicle 600 and other objects located around the vehicle 600 to generate observational data. The vehicle 600 may include a light detection and ranging (LiDAR) sensor as a sensor that serves a role similar to that of an external camera and a sonar. Examples of the position information acquisition system include a global navigation satellite system (GNSS), a real-time kinematic (RTK)-enabled device, and a LiDAR sensor.

The vehicle on-board sensor 610 collects moving body information, including vehicle information such as a vehicle identification number (VIN) of the vehicle 600 and information on a vehicle speed, a traveling direction, a traveling route, and a position of the vehicle 600.

The roadside sensors 900 shown in FIG. 1 are multiple sensors installed on the road. The roadside sensors 900 include, for example, multiple traffic lights 910, multiple roadside cameras 920, and LiDAR sensors installed on the road. Each traffic light 910 transmits information related to changes in the state of the traffic infrastructure, such as the time at which the traffic light 910 turns green and the time during which the traffic light 910 remains green, to the information processing system 10 via the external communication network 400.

Each roadside camera 920 collects observational data around the roadside camera 920. The observational data includes moving body information of multiple moving bodies 800 located around each roadside camera 920. The roadside cameras 920 include, for example, visible light cameras and infrared cameras. The LiDAR sensors installed on the road acquire point cloud data that is arranged in chronological order and continuously captured at fixed time intervals. Each LiDAR sensor collects the moving body information of moving bodies 800 located around the LiDAR sensor.

### Providing Traffic Services Based on Predicted Moving Body Information

The information processing system 10 is capable of transmitting predicted moving body information to the vehicle 600. The vehicle 600 is capable of providing the user of the vehicle 600 with traffic services based on the predicted moving body information acquired by the information processing system 10. The vehicle 600 includes vehicle on-board processing circuitry, a braking system, a steering system, directional indicators, speakers, and displays. The display of the vehicle 600 presents traffic services to the user of the vehicle 600. For example, the vehicle on-board processing circuitry of the vehicle 600 uses the predicted moving body information to show a vehicle approach notification or traffic information on the display of the vehicle 600. For example, the vehicle on-board processing circuitry of the vehicle 600 uses the predicted moving body information to issue a vehicle approach alert to the user of the vehicle 600 via the speakers of the vehicle 600. For example, the vehicle on-board processing circuitry of the vehicle 600 uses the predicted moving body information to control the braking system of the vehicle 600, thereby decelerating or stopping the vehicle 600. For example, the vehicle on-board processing circuitry of the vehicle 600 uses the predicted moving body information to control the steering system of the vehicle 600, thereby controlling the steering of the vehicle 600. The vehicle on-board processing circuitry may also control the directional indicators in addition to controlling the steering.

The information processing system 10 is capable of transmitting predicted moving body information to the information processing terminal 500. The information processing terminal 500 is capable of providing traffic services to the user of the information processing terminal 500 based on the predicted moving body information acquired by the information processing system 10. For example, the information processing terminal 500 uses the predicted moving body information to show a vehicle approach notification and traffic information on the display of the information processing terminal 500.

The information processing system 10 is capable of transmitting predicted moving body information to the traffic light 910. The traffic light 910 is capable of controlling its operation based on the predicted moving body information acquired by the information processing system 10. For example, the traffic light 910 is capable of controlling the time at which the traffic light 910 turns green and the time during which the traffic light 910 remains green based on the predicted moving body information. This enables the information processing system 10 to facilitate smooth traffic flow.

### Configuration of Information Processing System 10

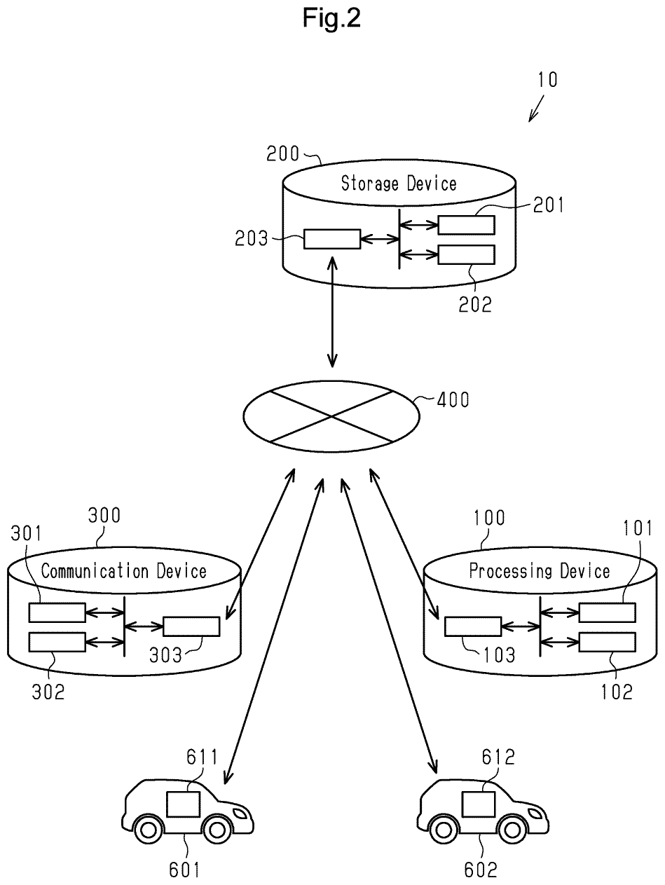

As illustrated in FIG. 2, the information processing system 10 includes a processing device 100, a storage device 200, and a communication device 300.

The processing device 100 includes first processing circuitry 101, first storage circuitry 102, and first communication circuitry 103. The first storage circuitry 102 stores programs. The first processing circuitry 101 executes the programs stored in the first storage circuitry 102 to execute various types of processes. The first processing circuitry 101 includes a processor. The processing device 100 is connected to the external communication network 400 via the first communication circuitry 103.

The storage device 200 includes second processing circuitry 201, second storage circuitry 202, and second communication circuitry 203. The second storage circuitry 202 stores programs. The second processing circuitry 201 executes the programs stored in the second storage circuitry 202 to execute various types of processes. The second processing circuitry 201 includes a processor. The storage device 200 is connected to the external communication network 400 via the second communication circuitry 203.

The communication device 300 includes third processing circuitry 301, third storage circuitry 302, and third communication circuitry 303. The third storage circuitry 302 stores programs. The third processing circuitry 301 executes the programs stored in the third storage circuitry 302 to execute various types of processes. The third processing circuitry 301 includes a processor. The communication device 300 is connected to the external communication network 400 via the third communication circuitry 303.

Each of the processing device 100, the storage device 200, and the communication device 300 includes processing circuitry including one or more processors that execute various processes in accordance with a computer program (software). Each of the processing device 100, the storage device 200, and the communication device 300 may include processing circuitry, including one or more dedicated hardware circuits such as an application-specific integrated circuit (ASIC), that executes at least a part of various processes. Alternatively, each of the processing device 100, the storage device 200, and the communication device 300 may include processing circuitry including a combination of one or more processors and one or more dedicated hardware circuits. The processor includes a CPU and a memory, such as a RAM and a ROM, and the memory stores program codes or instructions configured to have the CPU execute a process. The memory, which is a non-transitory computer readable storage medium, includes any type of media that are accessible by general-purpose computers and dedicated computers.

The configuration of the information processing system 10 is not limited to the one shown in FIG. 2. For example, the processing device 100, the storage device 200, and the communication device 300 may be included in a single server. For example, the processing device 100, the storage device 200, and the communication device 300 may be connected to each other via wired connections in a manner that allows mutual communication.

FIG. 2 illustrates a first vehicle 601 and a second vehicle 602 as examples of the moving bodies 800 for which the information processing system 10 calculates the predicted moving body information. The first vehicle 601 includes a first vehicle on-board sensor 611. The first vehicle on-board sensor 611 transmits the moving body information of the first vehicle 601 to the information processing system 10 via the external communication network 400. The second vehicle 602 includes a second vehicle on-board sensor 612. The second vehicle on-board sensor 612 transmits the moving body information of the second vehicle 602 to the information processing system 10 via the external communication network 400.

The communication device 300 sequentially acquires the moving body information transmitted from sensors at a predetermined acquisition cycle via the third communication circuitry 303. The communication device 300 stores the acquired moving body information in the third storage circuitry 302. The third processing circuitry 301 of the communication device 300 transmits the moving body information stored in the third storage circuitry 302 to the processing device 100 via the third communication circuitry 303.

The processing device 100 acquires the moving body information from the communication device 300 via the first communication circuitry 103. The processing device 100 stores the received moving body information in the first storage circuitry 102. The first processing circuitry 101 of the processing device 100 calculates predicted moving body information using the moving body information. The processing device 100 transmits the predicted moving body information to the storage device 200 via the first communication circuitry 103.

The storage device 200 receives the predicted moving body information via the second communication circuitry 203. The storage device 200 stores the acquired predicted moving body information in the second storage circuitry 202. In response to a request via the external communication network 400, the second processing circuitry 201 of the storage device 200 provides the predicted moving body information stored in the second storage circuitry 202.

The first vehicle 601 and the second vehicle 602 are examples of the moving bodies 800 for which the information processing system 10 calculates predicted moving body information. For example, the information processing system 10 calculates the predicted moving body information of the first vehicle 601 based on the moving body information acquired from the first vehicle on-board sensor 611. For example, the information processing system 10 calculates the predicted moving body information of the second vehicle 602 based on the moving body information acquired from the second vehicle on-board sensor 612.

The information processing system 10 updates predicted moving body information at the predetermined update cycle. When the update cycle of the predicted moving body information decreases, the amount of the predicted moving body information to be updated by the information processing system 10 per unit time increases. That is, when the update cycle of the predicted moving body information decreases, the processing load on the information processing system 10 increases. When the update cycle of the predicted moving body information increases, the deviation between the real-world position of the moving body 800 and the predicted position of the moving body 800 in the predicted moving body information may increase. Further, when the future position of the moving body 800 is predicted, the accuracy of the predicted position in the predicted moving body information of the moving body 800 may decrease. To solve this problem, the information processing system 10 determines an appropriate update cycle of the predicted moving body information by executing the following processes.

### Processes Executed by Information Processing System 10

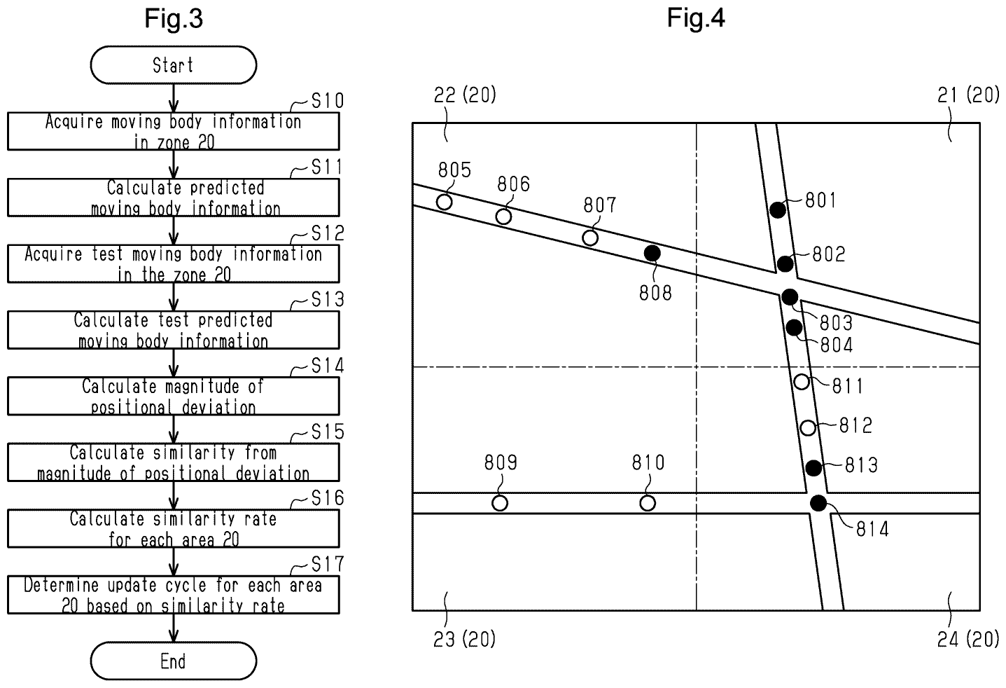

The flow of processes in which the information processing system 10 of the first embodiment determines the update cycle of the predicted moving body information will now be described with reference to FIGS. 3 to 7.

FIG. 3 is a flowchart illustrating a series of processes executed by the information processing system 10. The information processing system 10 repeatedly executes the series of processes.

As shown in FIG. 3, upon starting the series of processes, in step S10, the information processing system 10 first acquires the moving body information of moving bodies 800, located within multiple zones 20 shown in FIG. 4, via the third communication circuitry 303 of the communication device 300.

As shown in FIG. 4, the communication device 300 of the information processing system 10 sets the zones 20 used to calculate predicted moving body information to a first zone 21, a second zone 22, a third zone 23, and a fourth zone 24 based on information indicating latitude and longitude. The first zone 21 contains a first moving body 801, a second moving body 802, a third moving body 803, and a fourth moving body 804. The second zone 22 contains a fifth moving body 805, a sixth moving body 806, a seventh moving body 807, and an eighth moving body 808. The third zone 23 contains a ninth moving body 809 and a tenth moving body 810. The fourth zone 24 contains an eleventh moving body 811, a twelfth moving body 812, a thirteenth moving body 813, and a fourteenth moving body 814.

In the first embodiment, the processing device 100 updates the predicted moving body information for the moving bodies 800 contained within each zone 20 at the update cycle specified for the zone 20. For example, the processing device 100 updates the predicted moving body information for each of the first moving body 801, the second moving body 802, the third moving body 803, and the fourth moving body 804, which are contained within the first zone 21, at the same update cycle.

The communication device 300 may set the zone 20 to cover any range based on information other than latitude and longitude. For example, the communication device 300 may set the first zone 21 to a high-traffic zone in front of a station, set the second zone 22 to a residential zone with moderate traffic, and set the third zone 23 to a low-traffic mountainous area based on the traffic per unit time.

The moving body information acquired by the communication device 300 includes the position information, travel speed, travel direction, and type of each moving body 800. After the communication device 300 acquires the moving body information within a zone 20, the process proceeds to step S11.

In step S11, the processing device 100 calculates the predicted moving body information for each moving body 800.

For example, the processing device 100 estimates the possible route and position of the vehicle 600, which is the moving body 800, based on the position information, travel speed, and traveling direction of the vehicle 600. Further, the processing device 100 estimates the probability of the vehicle 600 being located at each position within the zone 20 based on the road information of the zone 20 obtained from the sensors. The road information of the zone 20 includes the signal displays installed on the lane in which the vehicle 600 is traveling, the presence or absence of road signs (e.g., no-entry signs), and the presence or absence of pedestrians 700 or buildings in the vicinity of the vehicle 600. For example, the likelihood of the vehicle 600 entering a road beyond a point where a no-entry road sign is installed is relatively low. Thus, the processing device 100 estimates that the probability of the vehicle 600 being located on a road beyond the point where the no-entry road sign is installed is relatively low. The processing device 100 may be configured to use a learning model trained through machine learning to estimate the possible route and position of the vehicle 600 and estimate the probability of the vehicle 600 being located at each position within the zone 20.

The processing device 100 calculates, as the predicted moving body information, a predicted position, where the vehicle 600 is estimated to be present at a predetermined time, based on the possible route and position of the vehicle 600 and the probability of the vehicle 600 being located at each position within the zone 20. The method by which the processing device 100 calculates the predicted moving body information for each moving body 800 is not limited to the method described above. The processing device 100 may calculate the predicted moving body information for each moving body 800 using a known prediction model.

After the processing device 100 calculates the predicted moving body information for each moving body 800, the process proceeds to step S12.

In step S12, the processing device 100 acquires test moving body information, which was acquired by the communication device 300 at a different time from the moving body information used to calculate the predicted moving body information and was stored in the third storage circuitry 302. In the first embodiment, the processing device 100 acquires, from the communication device 300, first moving body information as the test moving body information. The first moving body information was acquired by the communication device 300 at an earlier time than the moving body information used to calculate the predicted moving body information. After the processing device 100 acquires the first moving body information for each moving body 800 from the third storage circuitry 302 of the communication device 300, the process proceeds to step S13.

In step S13, the processing device 100 of the information processing system 10 calculates test predicted moving body information based on the test moving body information. The test predicted moving body information indicates the predicted position of the moving body 800 at the same time as the predicted moving body information. In the first embodiment, the processing device 100 calculates first test predicted moving body information using the first moving body information acquired from the communication device 300. After the processing device 100 calculates the first test predicted moving body information for each moving body 800, the process proceeds to step S14.

### Magnitude of Positional Deviation Between Predicted Center CP and Test Predicted Center CPT

In step S14, the processing device 100 calculates the magnitude of the positional deviation between a predicted center CP, which is the predicted position of the moving body 800 in the predicted moving body information, and a test predicted center CPT, which is the predicted position of the moving body 800 in the first test predicted moving body information.

The first storage circuitry 102 of the processing device 100 stores data on the dimensions of the moving body 800 for each type of the moving body 800. The first processing circuitry 101 of the processing device 100 calculates the predicted center CP based on the predicted moving body information and the data on the dimensions of the moving body 800 stored in the first storage circuitry 102. The first processing circuitry 101 of the processing device 100 calculates the test predicted center CPT based on the first test predicted moving body information and the data on the dimensions of the moving body 800 stored in the first storage circuitry 102.

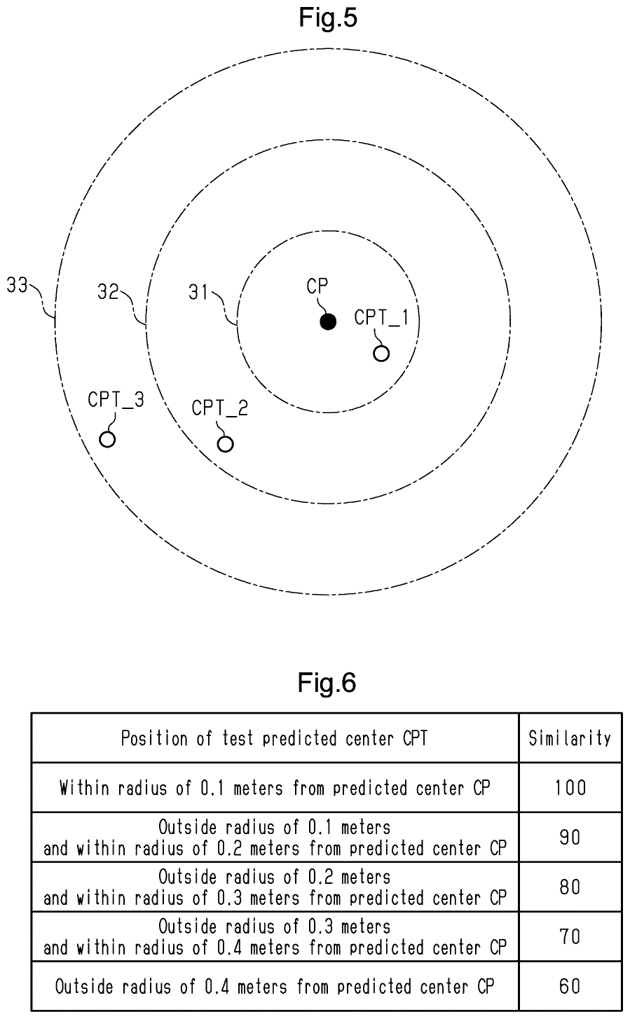

FIG. 5 is a schematic diagram illustrating the predicted center CP and the test predicted center CPT. A first circle 31 has a radius of 0.1 meters from the predicted center CP. A second circle 32 has a radius of 0.2 meters from the predicted center CP. A third circle 33 has a radius of 0.3 meters from the predicted center CP.

As shown in FIG. 5, a first test predicted center CPT_1 is a test predicted center CPT located within a radius of 0.1 meters from the predicted center CP. A second test predicted center CPT_2 is a test predicted center CPT that is located outside a radius of 0.1 meters and within a radius of 0.2 meters from the predicted center CP. A third test predicted center CPT_3 is a test predicted center CPT that is located outside a radius of 0.2 meters and within a radius of 0.3 meters from the predicted center CP.

After the processing device 100 calculates the magnitude of the positional deviation between the predicted center CP and the test predicted center CPT for each moving body 800, the process proceeds to step S15.

### Calculation of Similarity for Each Moving Body 800

In step S15, the processing device 100 calculates the similarity between the predicted moving body information and the first test predicted moving body information based on the magnitude of the positional deviation between the predicted center CP and the test predicted center CPT. The similarity between the predicted moving body information and the first test predicted moving body information is an index value that indicates the degree of similarity between the predicted moving body information and the first test predicted moving body information. The processing device 100 evaluates the correspondence relationship between the predicted moving body information and the first test predicted moving body information by calculating the index value that indicates the degree of similarity between the predicted moving body information and the first test predicted moving body information. In the information processing system 10 of the first embodiment, the index value includes the similarity and a similarity rate, which will be described later.

As shown in FIG. 6, when the position of the test predicted center CPT is located within a radius of 0.1 meters from the position of the predicted center CP, the processing device 100 calculates the similarity between the predicted moving body information and the first test predicted moving body information as 100. When the position of the test predicted center CPT is located outside a radius of 0.1 meters and within a radius of 0.2 meters from the position of the predicted center CP, the processing device 100 calculates the similarity between the predicted moving body information and the first test predicted moving body information as 90. When the position of the test predicted center CPT is located outside a radius of 0.2 meters and within a radius of 0.3 meters from the position of the predicted center CP, the processing device 100 calculates the similarity between the predicted moving body information and the first test predicted moving body information as 80. When the position of the test predicted center CPT is located outside a radius of 0.3 meters and within a radius of 0.4 meters from the position of the predicted center CP, the processing device 100 calculates the similarity between the predicted moving body information and the first test predicted moving body information as 70. When the position of the test predicted center CPT is located outside a radius of 0.4 meters from the position of the predicted center CP, the processing device 100 calculates the similarity between the predicted moving body information and the first test predicted moving body information as 60.

As shown in FIG. 5, the first test predicted center CPT_1 is located within a radius of 0.1 meters from the predicted center CP. Accordingly, as shown in FIG. 6, the similarity between the predicted moving body information and the first test predicted moving body information used to calculate the first test predicted center CPT_1 is calculated as 100. The second test predicted center CPT_2 is located outside a radius of 0.1 meters from the predicted center CP and within a radius of 0.2 meters from the predicted center CP. Accordingly, as shown in FIG. 6, the similarity between the predicted moving body information and the first test predicted moving body information used to calculate the second test predicted center CPT_2 is calculated as 90. The third test predicted center CPT_3 is located outside a radius of 0.2 meters from the predicted center CP and within a radius of 0.3 meters from the predicted center CP. Accordingly, as shown in FIG. 6, the similarity between the predicted moving body information and the first test predicted moving body information used to calculate the third test predicted center CPT_3 is calculated as 80.

The magnitude of the deviation between the predicted position of the moving body 800 in the predicted moving body information and the predicted position of the moving body 800 in the test predicted moving body information is not limited to the magnitude of the positional deviation between the predicted center CP and the test predicted center CPT. For example, the processing device 100 may calculate the magnitude of the deviation between the predicted position in the predicted moving body information and the predicted position in the first test predicted moving body information for characteristic parts of each moving body 800, such as the emblem of the vehicle 600. After the processing device 100 calculates the similarity for each moving body 800 located in the zone 20, the process proceeds to step S16.

### Calculation of Similarity Rate in Zone 20

In step S16, the processing device 100 calculates the similarity rate for each zone 20. The similarity rate is the proportion of moving bodies 800, out of all moving bodies 800 in each zone 20, with a similarity that is greater than or equal to a predetermined value. The similarity rate is an index value that indicates the degree of similarity. When being capable of properly determining the update cycle of the predicted moving body information for each zone 20, the processing device 100 is capable of setting the predetermined value to any value. For example, the processing device 100 may set the predetermined value to 80. In this case, the processing device 100 defines the proportion of moving bodies 800, out of all moving bodies 800 in each zone 20, with a similarity of 80 or greater as the similarity rate in the zone 20.

In FIG. 4, the moving bodies 800 with a similarity of below 80 are represented by black circles, and the moving bodies 800 with a similarity of 80 or greater are represented by blank circles. The first zone 21 contains the first moving body 801, the second moving body 802, the third moving body 803, and the fourth moving body 804. The first moving body 801, the second moving body 802, the third moving body 803, and the fourth moving body 804 are moving bodies 800 with a similarity rate of below 80. Therefore, the similarity rate in the first zone 21 is zero percent. The second zone 22 contains the fifth moving body 805, the sixth moving body 806, the seventh moving body 807, and the eighth moving body 808. The fifth moving body 805, the sixth moving body 806, and the seventh moving body 807 are moving bodies 800 with a similarity of 80 or greater. The eighth moving body 808 is a moving body 800 with a similarity of below 80. That is, the second zone 22 is a zone 20 where three out of the four moving bodies 800 have a similarity of 80 or greater. Thus, the similarity rate in the second zone 22 is 75 percent. The third zone 23 contains the ninth moving body 809 and the tenth moving body 810. The ninth moving body 809 and the tenth moving body 810 are moving bodies 800 with a similarity score of 80 or greater. Therefore, the similarity rate in the third zone 23 is 100 percent. The fourth zone 24 contains the eleventh moving body 811, the twelfth moving body 812, the thirteenth moving body 813, and the fourteenth moving body 814. The eleventh moving body 811 and the twelfth moving body 812 are moving bodies 800 with a similarity of 80 or greater. The thirteenth moving body 813 and the fourteenth moving body 814 are moving bodies 800 with a similarity of below 80. That is, the fourth zone 24 is a zone 20 where two out of the four moving bodies 800 have a similarity of 80 or greater. Thus, the similarity rate of the fourth zone 24 is 50 percent. After the processing device 100 calculates the similarity rate for each zone 20, the process proceeds to step S17.

### Determination of Update Cycle for Predicted Moving Body Information

In step S17, the processing device 100 determines the update cycle of the predicted moving body information for the moving bodies 800 located within each zone 20, based on the similarity rate for the zone 20. In the first embodiment, the information processing system 10 extends the update cycle of the predicted moving body information for the moving body 800 located within a zone 20 where the similarity rate is greater than or equal to 80 percent. The information processing system 10 does not modify the update cycle of the predicted moving body information for the moving body 800 located within the zone 20 where the similarity rate is less than 80 percent.

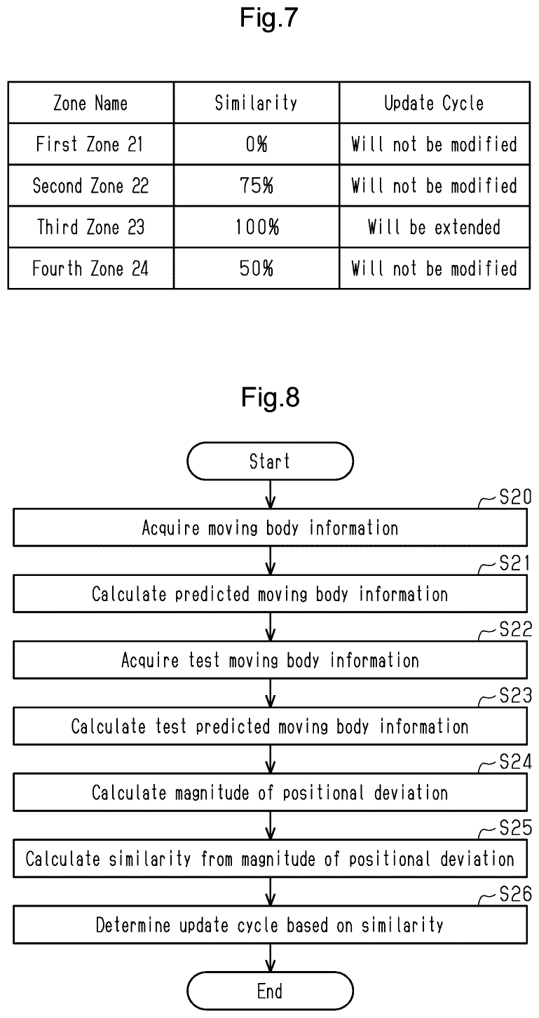

As shown in FIG. 7, the similarity rate in the first zone 21 is 0 percent. Thus, the processing device 100 does not modify the update cycle of the predicted moving body information for the moving body 800 located within the first zone 21. That is, the processing device 100 does not modify the update cycle of the predicted moving body information for the first moving body 801, the second moving body 802, the third moving body 803, and the fourth moving body 804, which are located within the first zone 21 shown in FIG. 4. As shown in FIG. 7, the similarity rate in the second zone 22 is 75 percent. Thus, the processing device 100 does not modify the update cycle of the predicted moving body information for the moving body 800 located within the second zone 22. That is, the processing device 100 does not modify the update cycle of the predicted moving body information for the fifth moving body 805, the sixth moving body 806, the seventh moving body 807, and the eighth moving body 808, which are shown in FIG. 4. The similarity rate of the third zone 23 is 100 percent. Thus, the processing device 100 extends the update cycle of the predicted moving body information for the moving body 800 located within the third zone 23. That is, the processing device 100 extends the update cycle of the predicted moving body information for the ninth moving body 809 and the tenth moving body 810. The similarity rate of the fourth zone 24 is 50 percent. Thus, the processing device 100 does not modify the update cycle of the predicted moving body information for the moving body 800 located within the fourth zone 24. That is, the processing device 100 does not modify the update cycle of the predicted moving body information for the eleventh moving body 811, the twelfth moving body 812, the thirteenth moving body 813, and the fourteenth moving body 814, which are shown in FIG. 4. After executing the process of step S17, the processing device 100 terminates the series of operations.

### Operation of First Embodiment

The longer the update cycle for updating predicted moving body information, the lower the processing load on the information processing system 10. As the update cycle for updating the predicted moving body information increases, the deviation between the real-world position of the moving body 800 and the predicted position of the moving body 800 in the predicted moving body information may increase. When the future position of the moving body 800 is predicted, the accuracy of the predicted position in the predicted moving body information of the moving body 800 may decrease. To solve this problem, the information processing system 10 determines the update cycle for updating the predicted moving body information while evaluating the correspondence relationship between multiple types of predicted moving body information calculated using the moving body information obtained at different times.

### Advantages of First Embodiment

(1-1) The information processing system 10 calculates highly accurate predicted moving body information while simultaneously reducing the processing load for updating the predicted moving body information.
(1-2) The processing device 100 of the information processing system 10 evaluates the correspondence relationship between the predicted moving body information and the first test predicted moving body information by calculating the similarity, which is the index value that indicates the degree of similarity between the predicted moving body information and the first test predicted moving body information. This allows the information processing system 10 to calculate highly accurate predicted moving body information while simultaneously reducing the processing load for updating the predicted moving body information.
(1-3) The processing device 100 of the information processing system 10 calculates the similarity between the predicted center CP and the test predicted center CPT for each moving body 800 located within a predetermined zone 20. Subsequently, the processing device 100 calculates the similarity rate, which is the proportion of the moving bodies 800 with a similarity that is greater than or equal to a predetermined threshold, based on the similarity for the moving bodies 800 in the predetermined zone 20. The similarity rate is an index value that indicates the degree of similarity. Based on the similarity rate, the processing device 100 determines the update cycle of the predicted moving body information for each predetermined zone 20. This allows the information processing system 10 to calculate highly accurate predicted moving body information for each zone 20 while simultaneously reducing the processing load for updating the predicted moving body information.
(1-4) The processing device 100 calculates the similarity between the predicted moving body information and the first test predicted moving body information. The first test predicted moving body information indicates the position of the moving body 800 at the same time as the predicted moving body information, the position being calculated from the first moving body information obtained by the communication device 300 at a time earlier than when the moving body information used to calculate the predicted moving body information was acquired. Specifically, the processing device 100 calculates the similarity between the predicted moving body information at a third time calculated from the moving body information acquired at a first time and the predicted moving body information at the third time calculated from the moving body information that was acquired at a second time. The second time is earlier than the first time. When the similarity between the predicted moving body information and the first test predicted moving body information has a relatively high value, the calculation of the predicted position of the moving body 800 using the first test predicted moving body information is performed with the same level of accuracy as that using the predicted moving body information. In this case, even if the update cycle for updating the predicted moving body information is extended, the processing device 100 calculates the predicted moving body information with the same level of accuracy as the current level. Thus, the processing device 100 of the information processing system 10 extends the update cycle of the predicted moving body information for the moving body 800 within the zone 20, based on a similarity rate that is greater than or equal to a predetermined value. This allows the information processing system 10 to extend the update cycle and thus reduce the processing load on the processing device 100, while maintaining the accuracy of the predicted moving body information.
(1-5) The information processing method executed by the information processing system 10 includes the step (step S10) that sequentially acquires the moving body information, which includes information indicating the position of a moving body 800 in the real world. The information processing method includes the step (step S11) that calculates the predicted moving body information, which indicates the predicted position of the moving body 800 at a time after the moving body information was acquired, based on the moving body information at a predetermined update cycle. The information processing method includes the steps (step S15 and step S16) that evaluate the correspondence relationship between the predicted position of the moving body 800 indicated by the predicted moving body information at the third time and calculated from the moving body information that was acquired at the first time and the predicted position of the moving body 800 indicated by the predicted moving body information at the third time and calculated from the moving body information that was acquired at the second time, which is different from the first time. The information processing method includes the step (step S17) that determines a predetermined update cycle based on the evaluation of the correspondence relationship. By executing such an information processing method, the information processing system 10 determines the update cycle for updating the predicted moving body information while evaluating the correspondence relationship between two types of predicted moving body information calculated using the moving body information obtained at different times. The execution of such an information processing method allows the information processing system 10 to calculate highly accurate predicted moving body information, while simultaneously reducing the processing load for updating the predicted moving body information.
(1-6) The first storage circuitry 102 of the processing device 100 of the information processing system 10 stores an information processing program that causes the first processing circuitry 101 of the processing device 100 to execute processes. The information processing program causes the processing device 100 to execute the predicted moving body information, which indicates the predicted position of the moving body 800 at a time after the moving body information was acquired, based on the moving body information at a predetermined update cycle. The information processing program causes the processing device 100 to evaluate the correspondence relationship between the predicted position of the moving body 800 indicated by the predicted moving body information at the third time and calculated from the moving body information that was acquired at the first time and the predicted position of the moving body 800 indicated by the predicted moving body information at the third time and calculated from the moving body information that was acquired at the second time, which is different from the first time. The information processing program causes the first processing circuitry 101 of the processing device 100 to determine a predetermined update cycle based on the evaluation of the correspondence relationship. The information processing program causes the information processing system 10 to determine the update cycle for updating the predicted moving body information while evaluating the correspondence relationship between two types of predicted moving body information calculated using the moving body information obtained at different times. This allows the information processing system 10 to calculate highly accurate predicted moving body information, while simultaneously reducing the processing load for updating the predicted moving body information.

### Modification of First Embodiment

The first embodiment may be modified as follows. The present embodiment and the following modifications can be combined as long as they remain technically consistent with each other.

When determining the update cycle for updating the predicted moving body information, the processing device 100 of the information processing system 10 may evaluate the correspondence relationship without calculating the index value. Then, the processing device 100 determines the update cycle based on the evaluation of the correspondence relationship. For example, the processing device 100 may calculate the correspondence relationship between the predicted center CP, which is the predicted position of the moving body 800 in the predicted moving body information, and the test predicted center CPT, which is the predicted position of the moving body 800 in the test predicted moving body information. In this case, the processing device 100 evaluates the magnitude of the positional deviation between the predicted center CP and the test predicted center CPT to evaluate the correspondence relationship. When the magnitude of the positional deviation is less than or equal to a predetermined standard, the processing device 100 determines that the predicted center CP has a correspondence relationship with the test predicted center CPT. When the magnitude of the positional deviation is greater than predetermined standard, the processing device 100 determines that the predicted center CP has no correspondence relationship with the test predicted center CPT. When evaluating that there is a correspondence relationship, the processing device 100 extends the update cycle for updating the predicted moving body information. When evaluating that there is no correspondence relationship, the processing device 100 does not modify the update cycle for updating the predicted moving body information. Instead, when evaluating that there is no correspondence relationship, the processing device 100 may shorten the update cycle of the predicted moving body information. This configuration allows the information processing system 10 to calculate highly accurate predicted moving body information, while simultaneously reducing the processing load for updating the predicted moving body information.

The moving body information used by the processing device 100 of the information processing system 10 to calculate the test predicted moving body information is not limited to the first moving body information acquired by the communication device 300 at a time before the moving body information used for calculating the predicted moving body information was acquired. In step S12 shown in FIG. 3, the processing device 100 may acquire second moving body information, which is acquired by the communication device 300 at a time after the moving body information used to calculate the predicted moving body information was acquired, as test moving body information. In this case, in step S13 shown in FIG. 3, the processing device 100 calculates the test predicted moving body information using the second moving body information. The test predicted moving body information calculated by the processing device 100 using the second moving body information is defined as second test predicted moving body information. In step S14 shown in FIG. 3, the processing device 100 may calculate the magnitude of the positional deviation between the predicted center CP and the test predicted center CPT in the second test predicted moving body information. In step S15 shown in FIG. 3, the processing device 100 may calculate the similarity between the predicted moving body information and the second test predicted moving body information from the magnitude of the positional deviation between the predicted center CP and the test predicted center CPT in the second test predicted moving body information. Specifically, the processing device 100 may calculate the similarity between the predicted moving body information at the third time calculated from the moving body information acquired at the first time and the predicted moving body information at the third time calculated from the moving body information acquired at the second time, which is later than the first time.

It is estimated that the second test predicted moving body information calculated based on the second moving body information, which is more recent moving body information, allows for calculation of the predicted position of the moving body 800 with higher accuracy than the predicted moving body information. Therefore, when the similarity between the predicted moving body information and the second test predicted moving body information is relatively high, the predicted position of the moving body 800 in the predicted moving body information is calculated with sufficiently high accuracy. In a case in which the predicted position of the moving body 800 in the predicted moving body information is highly accurate, even if the update cycle of the predicted moving body information is extended, the processing device 100 is estimated to be capable of calculating the predicted position of the moving body 800 in the predicted moving body information with the required accuracy. Accordingly, in step S16 shown in FIG. 3, the processing device 100 may calculate the similarity rate for each zone 20 on the condition that the similarity between the predicted moving body information and the second test predicted moving body information is greater than or equal to a predetermined value. This allows the information processing system 10 to reduce the processing load on the processing device 100, while maintaining the accuracy of the predicted moving body information.

When the predicted moving body information indicates the current predicted position of the moving body 800, the most recent moving body information is closest to the current real-world situation that is to be predicted. Thus, within the information acquired by the information processing system 10, the position of the moving body 800 in the most recent moving body information is optimal as a comparison target for verifying the accuracy of the predicted moving body information that indicates the current predicted position of the moving body 800. Therefore, in step S12 shown in FIG. 3, the processing device 100 may acquire the position of the moving body 800 from the most recent moving body information as test moving body information. The processing device 100 may calculate the position of the center C of the moving body 800 in the most recent moving body information based on the most recent moving body information and the data on the dimensions of the moving body 800. In step S13 shown in FIG. 3, the processing device 100 does not have to calculate the test predicted moving body information. In step S14 shown in FIG. 3, the processing device 100 may calculate the magnitude of the positional deviation between the center C of the moving body 800 in the most recent moving body information obtained by the communication device 300 and the predicted center CP. In step S15 shown in FIG. 3, the processing device 100 may calculate the similarity between the predicted moving body information and the most recent moving body information from the magnitude of the positional deviation between the center C of the moving body 800 in the most recent moving body information obtained by the communication device 300 and the predicted center CP. The processing device 100 determines the update cycle of the predicted moving body information based on the calculated similarity. Specifically, the processing device 100 may calculate the similarity between the predicted moving body information at the third time, which is calculated from the moving body information acquired at the first time, and the moving body information acquired at the second time, which is later than the first time. The third time is the current time. The second time is the time at which the communication device 300 acquired the most recent moving body information. The second time, at which the most recent moving body information was obtained, is extremely close to the third time. That is, the second time is substantially identical to the third time. This allows the information processing system 10 to calculate predicted moving body information that accurately reproduces the position of the moving body 800 in the real world, while also reducing the processing load on the processing device 100 to update the predicted moving body information.

There is a possibility that, when the similarity rate within a predetermined zone 20 is less than a predetermined value, the accuracy of the predicted moving body information for the moving body 800 located within the predetermined zone 20 is relatively low. To solve this problem, when the similarity rate in the predetermined zone 20 is smaller than the predetermined value, the processing device 100 of the information processing system 10 may shorten the update cycle of the predicted moving body information. This allows the information processing system 10 to reduce the processing load and maintain the accuracy of the predicted moving body information.

The predetermined value, which serves as a threshold used to determine whether to shorten the update cycle, may be smaller than 80 as described in the above-described embodiment.

### Second Embodiment

A second embodiment will now be described with reference to FIGS. 4, 6, and 8. The second embodiment will be described, focusing on the differences from the first embodiment. In the second embodiment, the information processing system 10 determines the update cycle of predicted moving body information for each moving body 800.

The possible travel speed of the moving body 800 varies depending on the type of the moving body 800. For example, the moving body 800 includes an object such as the vehicle 600, which has a wide range of travel speeds and the ability to travel at a relatively high speed. For example, the moving body 800 includes an object such as the pedestrian 700, which is assumed to move at a lower speed than the vehicle 600. For this reason, the information processing system 10 sets the initial value of the update cycle to a different value for each type of moving body 800. For example, the information processing system 10 sets the update cycle of the predicted moving body information for the vehicle 600 to be shorter than the update cycle of the predicted moving body information for the pedestrian 700.

### Acquisition of Moving Body Information and Calculation of Predicted Moving Body Information

FIG. 8 is a flowchart illustrating a series of processes executed by the information processing system 10 in the second embodiment. The information processing system 10 repeatedly executes the series of processes. As shown in FIG. 8, upon starting the series of processes, in step S20, the information processing system 10 first acquires the moving body information of the moving body 800 for which the predicted moving body information needs to be updated, via the third communication circuitry 303 of the communication device 300. After the communication device 300 acquires the moving body information within a zone 20, the process proceeds to step S21.

In step S21, the information processing system 10 calculates the predicted moving body information for each moving body 800. After the information processing system 10 calculates the predicted moving body information for each moving body 800, the process proceeds to step S22.

### Acquisition of Test Moving Body Information

In step S22, the information processing system 10 acquires the test moving body information in the zone 20. For example, the test moving body information acquired by the information processing system 10 is the first moving body information. Alternatively, the test moving body information acquired by the information processing system 10 may be the second moving body information. After the information processing system 10 acquires the test moving body information of each moving body 800, the process proceeds to step S23.

### Calculation of Test Predicted Moving Body Information

In step S23, the processing device 100 of the information processing system 10 calculates the test predicted moving body information based on the test moving body information. After the information processing system 10 calculates the test predicted moving body information for each moving body 800, the process proceeds to step S24.

### Calculation of Magnitude of Positional Deviation

In step S24, the processing device 100 calculates the magnitude of the positional deviation between the predicted center CP, which is the predicted position of the moving body 800 in the predicted moving body information, and the test predicted center CPT, which is the predicted position of the moving body 800 in the test predicted moving body information.

After the information processing system 10 calculates the magnitude of the positional deviation between the predicted center CP and the test predicted center CPT, the process proceeds to step S25.

### Calculation of Similarity

In step S25, the information processing system 10 calculates the similarity between the predicted moving body information and the test predicted moving body information for each moving body 800, based on the magnitude of the positional deviation between the predicted center CP and the test predicted center CPT for each moving body 800. The method for calculating the similarity is the same as the method described with reference to FIG. 6. After the processing device 100 calculates the similarity for each moving body 800 located within the zone 20, the process proceeds to step S26.

### Determination of Update Cycle of Predicted Moving Body Information

In step S26, the processing device 100 determines the update cycle of the predicted moving body information for each moving body 800 based on the similarity calculated for the moving body 800. The processing device 100 extends the update cycle of the predicted moving body information for the moving body 800 with a similarity of 80 or greater. The processing device 100 does not modify the update cycle of the predicted moving body information for the moving body 800 with a similarity of below 80.

In the zones 20 shown in FIG. 4, the first moving body 801, the second moving body 802, the third moving body 803, the fourth moving body 804, the eighth moving body 808, the thirteenth moving body 813, and the fourteenth moving body 814 are moving bodies 800 with a similarity of below 80. The processing device 100 does not modify the update cycle of the predicted moving body information for the first moving body 801, the second moving body 802, the third moving body 803, the fourth moving body 804, the eighth moving body 808, the thirteenth moving body 813, and the fourteenth moving body 814. In the zones 20 shown in FIG. 4, the fifth moving body 805, the sixth moving body 806, the seventh moving body 807, the ninth moving body 809, the tenth moving body 810, the eleventh moving body 811, and the twelfth moving body 812 are moving bodies 800 with a similarity of 80 or greater. The processing device 100 extends the update cycle of the predicted moving body information for the fifth moving body 805, the sixth moving body 806, the seventh moving body 807, the ninth moving body 809, the tenth moving body 810, the eleventh moving body 811, and the twelfth moving body 812.

After executing the process in step S26, the processing device 100 terminates the series of operations.

### Operation of Second Embodiment

The travel speed of the moving body 800 in the real world varies for each moving body 800. For example, the vehicle 600 includes a vehicle 600 that is traveling at a relatively high speed and a stationary vehicle 600. Accordingly, the processing device 100 determines the update cycle of the predicted moving body information for each moving body 800.

### Advantages of Second Embodiment

(2-1) The information processing system 10 calculates highly accurate predicted moving body information for each moving body 800, while simultaneously reducing the processing load for updating the predicted moving body information.
(2-2) The processing device 100 sets the initial value of the update cycle of the predicted moving body information for each type of moving body 800. This allows the information processing system 10 to determine the update cycle more accurately, as compared to setting a uniform initial value to the update cycle regardless of the type of moving body 800. Consequently, the processing load decreases.

### Modification of Second Embodiment

The above-described second embodiment may be modified as follows. The second embodiment and the following modifications can be combined as long as the combined modifications remain technically consistent with each other.

When the similarity of the moving body 800 is less than a predetermined value, the accuracy of the predicted moving body information for the moving body 800 is relatively low. To solve this problem, the processing device 100 of the information processing system 10 may shorten the update cycle of the predicted moving body information for a moving body 800 having a similarity of below the predetermined value. This allows the information processing system 10 to reduce the processing load and maintain the accuracy of the predicted moving body information.

In the second embodiment, the information processing system 10 determines the update cycle of the predicted moving body information for each moving body 800, based on the similarity between the predicted moving body information and the first test predicted moving body information. In this case, the information processing system 10 may store the first time, at which the moving body information used to calculate the predicted moving body information was acquired, and the second time, at which the first moving body information used to calculate the first test predicted moving body information was acquired. In a case in which the similarity is greater than or equal to a predetermined value, as the interval between the first time and the second time increases, the information processing system 10 accurately reproduces the moving body information based on older moving body information. In a case in which the similarity between the predicted moving body information of a moving body 800 and the first test predicted moving body information is greater than or equal to the predetermined value, as the interval between the first time and the second time increases, the information processing system 10 may set the update cycle of the predicted moving body information for the moving body 800 to be longer. This allows the information processing system 10 to further reduce the processing load, while limiting accuracy degradation caused by changes in the update cycle.

If the communication device 300 can continuously update the predicted moving body information at an appropriate update cycle, the type of each moving body 800 does not have to be acquired as part of the moving body information.

### Another Modification

The following is a modification commonly applicable to each of the above-described embodiments. The following modification can be combined as long as the combined modification remains technically consistent with each other.

The processing device 100 of the information processing system 10 may acquire the test moving body information from circuitry other than the third storage circuitry 302 of the communication device 300. For example, the processing device 100 may be configured to store the test moving body information in the first storage circuitry 102 of the processing device 100. In this case, the first processing circuitry 101 of the processing device 100 acquires the test moving body information from the first storage circuitry 102.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. An information processing system, comprising:
a communication device configured to sequentially acquire moving body information, the moving body information including information that indicates a position of a moving body located in a real world; and
a processing device configured to calculate predicted moving body information based on the moving body information at a predetermined update cycle, the predicted moving body information indicating a predicted position of the moving body at a time after the moving body information was acquired, and
the processing device is configured to:
evaluate a correspondence relationship between a position of the moving body indicated by the predicted moving body information at a third time and calculated from moving body information that was acquired at a first time and a position of the moving body at the third time acquired from moving body information that was acquired at a second time, the second time being different from the first time; and
determine the predetermined update cycle based on the evaluation.

2. The information processing system according to claim 1, wherein
the processing device is configured, to evaluate the correspondence relationship, to:
evaluate an index value that indicates a degree of similarity between the position of the moving body indicated by the predicted moving body information at the third time and calculated from the moving body information that was acquired at the first time and the position of the moving body at the third time acquired from the moving body information that was acquired at the second time; and
determine the predetermined update cycle based on the index value.

3. The information processing system according to claim 2, wherein
the processing device is configured, for each of multiple predetermined zones, to:
calculate the predicted moving body information at the predetermined update cycle;
calculate the index value; and
determine the predetermined update cycle based on the index value.

4. The information processing system according to claim 2, wherein
the moving body is one of moving bodies, and
the processing device is configured to:
calculate the index value for each of the moving bodies; and
determine the predetermined update cycle based on the index value for each of the moving bodies.

5. The information processing system according to claim 4, wherein
the moving body information includes information indicating a type of each of the moving bodies, and
the processing device is configured to set an initial value of the update cycle for each of the types of the moving bodies.

6. The information processing system according to claim 2, wherein
the second time is earlier than the first time,
the index value indicates a degree of similarity between the predicted moving body information at the third time calculated from the moving body information that was acquired at the first time and first test predicted moving body information, wherein the first test predicted moving body information indicates information on the position of the moving body at the third time and is calculated from first moving body information that was acquired at the second time; and
the processing device is configured to extend the predetermined update cycle when the index value is greater than or equal to a predetermined value.

7. The information processing system according to claim 2, wherein
the second time is later than the first time,
the index value indicates a degree of similarity between the predicted moving body information at the third time calculated from the moving body information that was acquired at the first time and second test predicted moving body information, wherein the second test predicted moving body information indicates information on the position of the moving body at the third time and is calculated from second moving body information that was acquired at the second time; and
the processing device is configured to extend the predetermined update cycle when the index value is greater than or equal to a predetermined value.

8. The information processing system according to claim 2, wherein
the third time is a current time,
the second time is later than the first time and is a time at which the communication device acquired most recent moving body information,
the index value indicates a degree of similarity between the predicted moving body information at the third time calculated from the moving body information that was acquired at the first time and the most recent moving body information acquired by the communication device, and
the processing device is configured to extend the predetermined update cycle when the index value is greater than or equal to a predetermined value.

9. The information processing system according to claim 6, wherein
the processing device is configured to shorten the predetermined update cycle when the index value is less than the predetermined value.

10. The information processing system according to claim 7, wherein the processing device is configured to shorten the predetermined update cycle when the index value is less than the predetermined value.

11. The information processing system according to claim 8, wherein the processing device is configured to shorten the predetermined update cycle when the index value is less than the predetermined value.

12. The information processing system according to claim 6, wherein the processing device is configured to modify the update cycle to be longer as an interval between the first time and the second time increases.

13. An information processing method, comprising:
sequentially acquiring moving body information, the moving body information including information that indicates a position of a moving body located in a real world;
calculating predicted moving body information based on the moving body information at a predetermined update cycle, the predicted moving body information indicating a predicted position of the moving body at a time after the moving body information was acquired, and
evaluating a correspondence relationship between a position of the moving body indicated by the predicted moving body information at a third time and calculated from moving body information that was acquired at a first time and a position of the moving body at the third time acquired from moving body information that was acquired at a second time, the second time being different from the first time; and
determining the predetermined update cycle based on the evaluation.

14. A non-transitory computer readable storage medium storing an information processing program executed by a processing device of an information processing system, the information processing system including a communication device configured to sequentially acquire moving body information, the moving body information including information indicating a position of a moving body located in a real world, wherein
the information processing program causes the processing device to execute:
calculating predicted moving body information based on the moving body information at a predetermined update cycle, the predicted moving body information indicating a predicted position of the moving body at a time after the moving body information was acquired;
evaluating a correspondence relationship between a position of the moving body indicated by the predicted moving body information at a third time and calculated from moving body information that was acquired at a first time and a position of the moving body at the third time acquired from moving body information that was acquired at a second time, the second time being different from the first time; and
determining the predetermined update cycle based on the evaluation.
